(19) United States
(12) Patent Application Publication
(10) Pub. No.: US 2002/0152950 A1
(43) Pub. Date: Oct. 24, 2002

(54) Method and device for controlling a crystal pulling apparatus

(76) Inventor: Joachim Aufreiter, Alzenau (DE)

Correspondence Address: NEEDLE & ROSENBERG, P.C., The Candler Building, Suite 1200, 127 Peachtree Street, N.E., Atlanta, GA, 30303-1811, US

(21) Appl. No.: 10/131,530

(22) Filed: Apr. 24, 2002

(30) Foreign Application Priority Data
Apr. 24, 2001 (DE) 101 19 947.3

(51) Int. Cl. C30B 15/00; C30B 21/06; C30B 27/02; C30B 28/10; C30B 30/04

(52) U.S. Cl. 117/14; 117/13; 117/15

(57) ABSTRACT

The present invention relates to a method and device for controlling a crystal pulling apparatus while pulling a single crystal according to the Czochralski method. To this end, a crystal pulling apparatus is provided which has a vertically adjustable crucible, a heater surrounding at least a portion of the crucible, a pulling device operatively disposed over the crucible, and a control circuit operatively connected to the pulling device and the crucible. The heater is energized to form a molten mass in the crucible and the pulling device is actuated to pull a crystal from the molten mass. Through a control circuit, the crucible with the crystal can be adjusted in height relative to a heater, so that the upper edge of the heater juts to a greater or lesser degree over the crucible. The crystal pulling apparatus may also have a vertically adjustable funnel that surrounds the crystal and is positioned over and above the molten mass within the crucible leaving open a gap between a melt level of the molten mass and the lower edge of the funnel. This funnel is adjustable in height above the melt level by means of an actuator.

This application claims priority to German Patent Application No. 101 19 947.3 filed on Apr. 24, 2001, which application is incorporated herein in its entirety.

### BACKGROUND OF THE INVENTION

1. Field of the Invention

The invention relates to a method and to a device for controlling a crystal pulling apparatus during crystal formation according to the Czochralski method, more particularly to a method and device for controlling the crystal pulling apparatus so that a crystal of substantially constant diameter is produced.

2. Background Art

The invention relates to a method and device for controlling a crystal pulling apparatus. The crystal pulling apparatus of the present invention has a height-adjustable crucible that is surrounded by a heater and a pulling device suspended or placed over the crucible. Typically, the crucible is used to produce a molten mass and the pulling device pulls a crystal from the molten mass at a rate corresponding to the crystal growth. A control circuit for achieving a constant diameter of the crystal is provided.

A typical crystal pulling apparatus, which works according to the Czochralski method, is described, for example, in German Patent 28 21 481 A1. To monitor the diameter of the resulting crystal, the use of an optical sensor is known in practice. Further, as shown in European Patent 0 781 873 A2, in crystal pulling apparatuses in which the crystal is moved in the drawing direction by a rope coiled around a rope drum, it is known to constantly monitor the weight of the crystal through weight measuring cells and to adjust the velocity of pulling in response to the monitored weight of the crystal.

In practice, during the course of pulling the crystal, if the diameter of the crystal begins to deviate from a desired value, it is normal to initially change the velocity of pulling. After about 10 to 30 seconds, the change in velocity of pulling results in a change in the diameter of the crystal. Thus, changing the velocity of pulling allows for a quick intervention method to prevent undesired growth of the diameter of the crystal.

Since the optimal range of the velocity of pulling is limited, other methods must be used when there are greater deviations from the desired value in order to influence the crystal growth. To this end, it is known that changing the heating capacity of the heater of the crucible changes the temperature of the molten mass in the crucible. However, in comparison to the previously described quick intervention of changing the velocity of pulling the crystal, the disadvantage of changing the temperature of the molten mass in the crucible is that a change in the diameter of the resulting crystal occurs only after about 30 minutes. Thus, this type of intervention represents a very sluggish control, which results in crystals with sufficiently even diameter and sufficient crystal properties only in combination with the previously mentioned change in the velocity of pulling. It is disadvantageous, however, to compensate for the disadvantages of controlling the crystallization through the heating capacity of the crucible by changing the velocity of pulling, because fluctuations in the velocity of the pulling inevitably lead to fluctuations in the quality of the crystal produced; thus, one takes great pains to make the velocity of pulling as even as possible, so that the resulting crystal properties are as even and satisfactory as possible.

One object of the invention is to provide a method for controlling a crystal pulling apparatus that results in as even a velocity of pulling as possible. Furthermore, a device for implementing this method should be created.

### SUMMARY

The present invention relates to a method and device for controlling a crystal pulling apparatus while pulling a single crystal according to the Czochralski method. To this end, a crystal pulling apparatus is provided which has a vertically adjustable crucible, a heater surrounding at least a portion of the crucible, a pulling device operatively disposed over the crucible, and a control operatively connected to the pulling device and the crucible. The heater is energized to form a molten mass in the crucible and the pulling device is actuated to pull a crystal from the molten mass. The component parts of the crystal pulling apparatus are moved in a vertical direction so that the level of a solidification line in the crystal is controlled which allows for control over the diameter of the crystal.

The crystal pulling apparatus may also include a vertically adjustable funnel that surrounds the crystal and is positioned over and above the molten mass within the crucible. A gap is formed between a lower edge of the funnel and the melt level of the molten mass. The apparatus also includes means for adjusting the size of the gap by moving the funnel relative to the melt level of the molten mass within the crucible.

### BRIEF DESCRIPTION OF THE DRAWINGS

The accompanying drawing, which is incorporated in and constitutes a part of this specification, illustrates several embodiments of the invention and together with the description, serves to explain the principals of the invention.

FIG. 1 is a schematic drawing of a crystal pulling apparatus with a control for the pulling process.

### DETAILED DESCRIPTION OF THE INVENTION

The present invention is more particularly described in the following examples that are intended to be illustrative only since numerous modifications and variations therein will be apparent to those skilled in the art. As used in the specification and in the claims, the singular form “a,” “an” and “the” include plural referents unless the context clearly dictates otherwise.

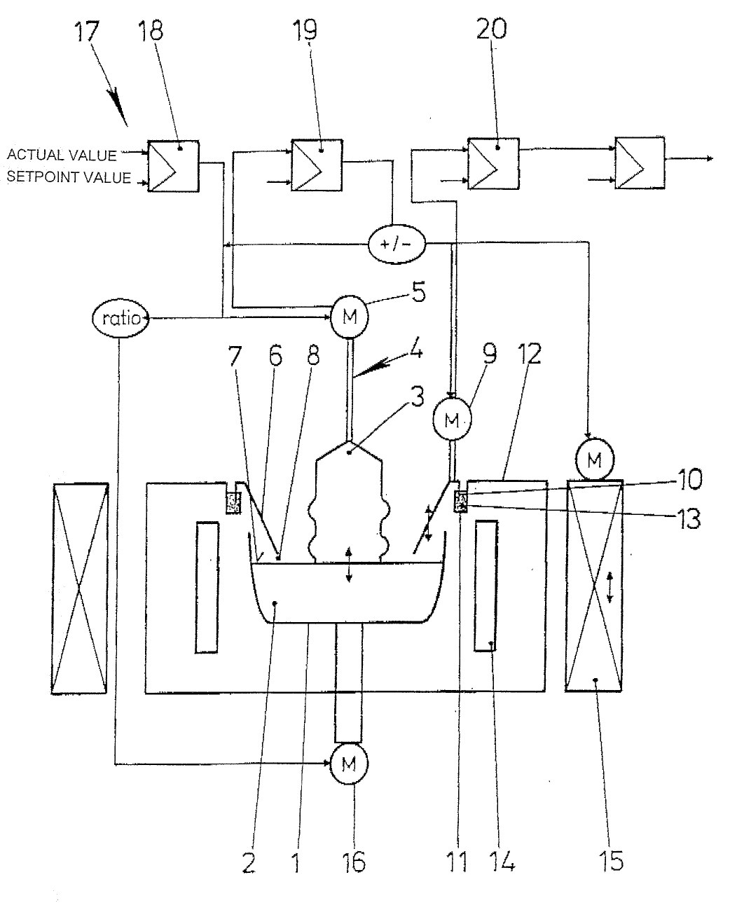

The referenced problems are solved and the objects are achieved by the arrangement described hereinafter and by the proposed method according to the invention. Referring to FIG. 1, a crucible 1, in which a molten mass 2 is found, from which a crystal 3 is pulled, is shown. This crystal 3 can be extracted from the molten mass 2 at a velocity of pulling necessary for the crystal growth by means of a pulling device 4, which exhibits a motor 5. As is normally the case in crystal pulling apparatuses that work according to the Czochralski process, the crucible 1 is surrounded by a heater 14 and this, in turn, is surrounded by a vertically adjustable magnet 15. The height of the crucible 1 can be adjusted by means of a motor 16. A control 17 is shown schematically above the component parts described. This is able to control the motors 5 and 16 by means of a diameter control 18, so that the crucible 1 with the crystal 3 is able to move upwards or downwards relative to the heater 14.

The first-mentioned task is solved according to the invention in that, to control the diameter, the components of the crystal pulling apparatus that influence the temperature in the solidification range are moved in a vertical direction.

Through this method, one can respond very quickly, without changing the velocity of pulling, to the parameter that influences the crystal growth, for example, a decrease in the temperature of the molten mass. The method of the invention also results in improved crystal properties. For example, increases in the crystal can be minimized or distributed more evenly. Furthermore, more even radial gradients appear in the crystallization.

The solidification range can be influenced in different ways. An advantageous possibility in existing pulling apparatuses is to change, without changing the pulling apparatuses, the position between the crucible and the crystal, on the one hand, and the heater, on the other hand, in order to control the diameter of the crystal.

The method of the present invention is particularly effective when the height of the crucible and the crystal are synchronously adjusted to control the diameter of the crystal. As a result, the crystal dips deeper into the heater or juts out further from it so that more or less heat from the heater reaches the crystal, and, as a result, the solidification line of the crystal moves.

According to another embodiment of the method according to the invention, the crystal pulling apparatus used to implement the method has a vertically adjustable funnel placed above the molten mass and surrounding the crystal. In this embodiment, the distance of a lower edge 10 of a funnel 6 from a melt level 7 of the molten mass 2 can be changed to control the diameter of the crystal. Through such changes in the “gap” distance, the amount of heat reaching the crystal can likewise be changed very rapidly so that, even when there are deviations in the method parameters, the velocity of pulling can be constantly maintained. Of course, it is also possible, through the vertical adjustability of the funnel, to also keep the size of the gap constant when the height of the crucible is adjusted.

In this alternative embodiment, the crystal 3 is surrounded by a vertically adjustable funnel 6 that extends upwards. The melt level 7 of the molten mass does not quite reach a lower edge of the funnel 6 so that a gap 8 remains between the melt level 7 and the lower edge of the funnel 6. The size of this gap 8 is be changed by means of an actuator 9, which is able to adjust the height of the funnel 6. Furthermore, the control 17 exhibits a velocity of pulling controller 19 and a null position controller 20. This null position controller 20 controls the actuator 9, and as a result, is able to lift or lower the funnel 6 to change the size of the gap 8 so that the solidification line for the crystal 3 can be moved.

Thus, by using a vertically adjustable funnel above the molten mass found in a crucible, with the funnel surrounding the crystal and spaced from the melt level of the molten mass, control of over the diameter of the crystal is maintained by positioning the funnel by means of an actuator above the melt level in a height-adjustable manner. Such an adjustment of the funnel may be implemented with very little expense so that the solidification line of the crystal can be adjusted without the apparatus having to be constructed at great expense.

The sealing of the funnel against the cover of the heater can be done in a simple manner despite the possibility of height adjustment if, according to a further embodiment of the invention, the funnel 6 has on its upper side an upper edge 10 directed downwards, which engages in a rotating sealing channel 11 of a heater cover 12. The sealing is realized in a particularly cost-effective manner when the sealing channel contains quartz wool 13.

The invention has been described herein in detail, in order to comply with the Patent Statutes and to provide those skilled in the art with information needed to apply the novel principles, and to construct and use such specialized components as are required. However, it is to be understood, by those skilled in the art, that the invention can be carried out by specifically different equipment and devices, and that various modifications, both as to equipment details and operating procedures can be affected without departing from the scope of the invention itself. Further, it should be understood that, although the present invention has been described with reference to specific details of certain embodiments thereof, it is not intended that such details should be regarded as limitations upon the scope of the invention except as and to the extent that they are included in the accompanying claims.

What is claimed is:

1. A method for pulling a crystal having a substantially constant diameter comprising the steps of:
a) providing a crystal pulling apparatus, the crystal pulling apparatus having a vertically adjustable crucible, a heater surrounding at least a portion of the crucible, a pulling device operatively disposed over the crucible, and a control circuit operatively connected to the pulling device and the crucible;
b) energizing the heater to form a molten mass in the crucible;
c) actuating the pulling device to pull the crystal from the molten mass in a vertical direction corresponding to the crystal growth; and
d) moving the component parts of the crystal pulling apparatus in a vertical direction to influence the level of a solidification line in the crystal so that the diameter of the crystal is controlled.

2. The method of claim 1, wherein the pulling device pulls the crystal at a substantially constant velocity.

3. The method of claim 1, wherein the relative position between the crucible and the crystal is changed with respect to the heater to control the diameter of the crystal.

4. The method of claim 3, wherein the heights of the crucible and the crystal are synchronously adjusted with respect to the heater to control the diameter of the crystal.

5. The method of claim 1, wherein the crystal pulling apparatus has a funnel surrounding the crystal, the funnel positioned above the molten mass, wherein the crystal pulling apparatus defines a gap between a lower edge of the funnel and a melt level of the molten mass, and wherein the funnel is moved in a vertical direction relative to the melt level of the molten mass in the crucible to change the size of the gap to control the diameter of the crystal.

6. A crystal pulling apparatus for pulling a crystal having a substantially constant diameter from a molten mass, the apparatus comprising:
a) a vertically adjustable crucible, the molten mass disposed in the crucible and forming a melt level of the molten mass in the crucible;
b) a heater surrounding at least a portion of the crucible,
c) a pulling device operatively disposed over the crucible in operative contact with the crystal;
d) a control circuit operatively connected to the pulling device and the crucible;
e) a vertically adjustable funnel having a lower edge and a downwardly extending upper edge, the funnel surrounding the crystal pulled from the molten mass, the lower edge of the funnel and the melt level of the molten mass defining a gap therebetween; and
f) means for adjusting the height of the lower edge of the funnel relative to the melt level of the molten mass in the crucible to change the size of the gap between the melt level and the lower edge of the funnel so that the diameter of the crystal may be controlled.

7. The crystal pulling apparatus of claim 6, wherein the crucible has a sealing channel that surrounds the crucible, and wherein the upper edge of the funnel is positioned within the sealing channel.

8. The crystal pulling apparatus of claim 7, wherein the sealing channel contains quartz wool, and wherein the upper edge of the funnel contact the quartz wool.
